(19) United States
(12) Patent Application Publication
(10) Pub. No.: US 2016/0079477 A1
(43) Pub. Date: Mar. 17, 2016

(54) SEMICONDUCTOR LIGHT-EMITTING ELEMENT

(71) Applicant: KABUSHIKI KAISHA TOSHIBA, Tokyo (JP)

(72) Inventor: Tadashi MATSUNO, Kanazawa Ishikawa (JP)

(21) Appl. No.: 14/634,887

(22) Filed: Mar. 1, 2015

(30) Foreign Application Priority Data
Sep. 16, 2014 (JP) 2014-188076

(51) Int. Cl. H01L 33/38

(52) U.S. Cl. CPC H01L 33/382; H01L 33/387

(57) ABSTRACT

A semiconductor light-emitting element is provided. The semiconductor light-emitting element including a first semiconductor layer of a first conductivity type, a second semiconductor layer of a second conductivity type, and a light-emitting layer between the first semiconductor layer and the second semiconductor layer, wherein the light emitting layer has a light-emitting surface facing the second semiconductor layer. The semiconductor light-emitting element further includes a first electrode pad; and a first wiring connected to the first electrode pad. The first wiring has a length and a width each substantially parallel to the light-emitting surface. The length is greater than the width, and the width changes between a first portion and a second portion. The first portion is closer to the first electrode pad than the second portion is to the first electrode pad.

### CROSS-REFERENCE TO RELATED APPLICATION

This application is based upon and claims the benefit of priority from Japanese Patent Application No. 2014-188076, filed Sep. 16, 2014, the entire contents of which are incorporated herein by reference.

### FIELD

Embodiments described herein relate generally to a semiconductor light-emitting element.

### BACKGROUND

A semiconductor light-emitting element such as an LED (Light Emitting Diode) includes a light-emitting layer which is interposed between a p-type semiconductor layer and an n-type semiconductor layer. By applying a forward bias voltage between the p-type semiconductor layer and the n-type semiconductor layer, a positive hole and an electron are recombined in the light-emitting layer and a photon is emitted from the light-emitting layer.

For example, in a structure in which the n-type semiconductor layer is positioned above the p-type semiconductor layer, an electrode pad is provided on the n-type semiconductor layer. A potential is supplied to this electrode pad from the outside. Furthermore, on the n-type semiconductor layer, a wiring is connected to the electrode pad, and the potential of the electrode pad is applied to the wiring. Here, in order to thoroughly apply the potential of the electrode pad to the entirety of the wiring, it is desired that the width of the wiring become larger to reduce the resistance of the wiring.

However, if the width of the wiring is too large, the light emitted from the light-emitting layer will be shielded or blocked by the wiring itself. For this reason, the width of the wiring is required to be equal to or lower than a predetermined width. However, in this regard, if the width of the wiring is made smaller, the resistance of the wiring will be increased and thus a voltage drop in the wiring is increased. When accounting for the voltage drop in the wiring, it is not easy to evenly apply the potential to the n-type semiconductor layer. Therefore, a high light-emitting efficiency may not be obtained in some cases when the wiring is narrow.

### DESCRIPTION OF THE DRAWINGS

FIG. 1A is a top view schematically illustrating a semiconductor light-emitting element according to a first embodiment, and FIG. 1B is a cross-sectional view schematically illustrating the semiconductor light-emitting element according to the first embodiment, and FIG. 1C is a bottom view schematically illustrating the semiconductor light-emitting element according to the first embodiment.

FIG. 2A is a top view schematically illustrating an operation in the semiconductor light-emitting element according to the first embodiment, and FIG. 2B is a diagram illustrating an example of relationship between the width of a wiring of the semiconductor light-emitting element and light-emitting efficiency according to the first embodiment.

FIG. 3A is a top view schematically illustrating a semiconductor light-emitting element according to a first modification example of the first embodiment, and FIG. 3B is a top view schematically illustrating the semiconductor light-emitting element according to a second modification example of the first embodiment.

FIG. 4A is a top view schematically illustrating a semiconductor light-emitting element according to a second embodiment, and FIG. 4B is a cross-sectional view schematically illustrating the semiconductor light-emitting element according to the second embodiment, and FIG. 4C is a bottom view schematically illustrating the semiconductor light-emitting element according to the second embodiment.

FIG. 5 is a bottom view schematically illustrating a semiconductor light-emitting element according to a first modification example of the second embodiment.

FIG. 6A is a top view schematically illustrating a semiconductor light-emitting element according to a third embodiment, and FIG. 6B is a bottom view schematically illustrating the semiconductor light-emitting element according to the third embodiment.

FIG. 7 is a top view schematically illustrating a semiconductor light-emitting element according to a fourth embodiment.

### DETAILED DESCRIPTION

An object of exemplary embodiments is to provide a semiconductor light-emitting element capable of obtaining high light-emitting efficiency.

In general, according to one embodiment, a semiconductor light-emitting element is provided. The semiconductor light-emitting element includes a first semiconductor layer of a first conductivity type, a second semiconductor layer of a second conductivity type, and a light-emitting layer between the first semiconductor layer and the second semiconductor layer, wherein the light emitting layer has a light-emitting surface facing the second semiconductor layer. The semiconductor light-emitting element further includes a first electrode pad and a first wiring connected to the first electrode pad. The first wiring has a length and a width each substantially parallel to the light-emitting surface. The length is greater than the width, and the width changes between a first portion and a second portion. The first portion is closer to the first electrode pad than the second portion is to the first electrode pad.

Hereinafter, the description is given of an example embodiment with reference to the drawings. The same reference numerals are given to portions substantially similar to those used in previous drawings and descriptions. Descriptions regarding portions already described may be omitted for subsequently described embodiments.

### First Embodiment

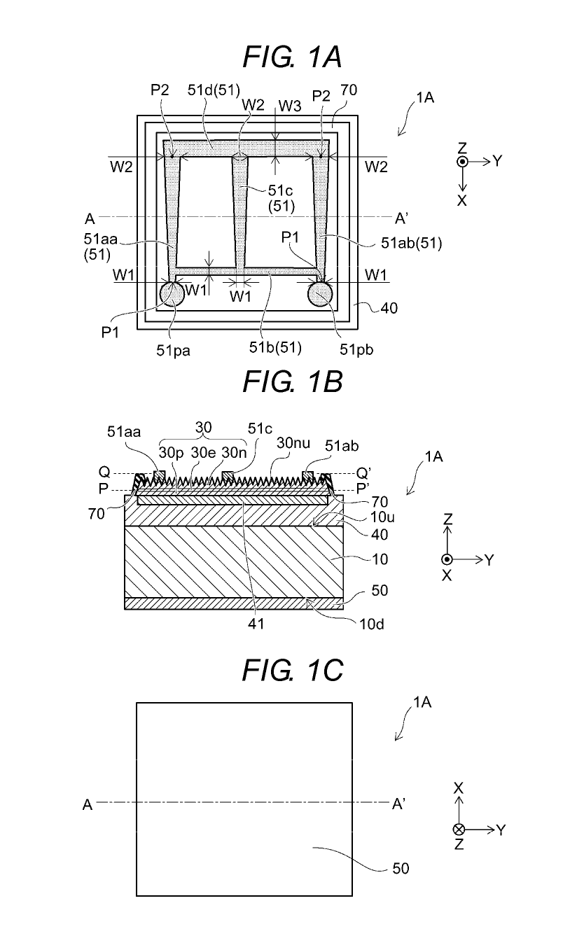

FIG. 1A is a top view schematically illustrating a semiconductor light-emitting element according to a first embodiment, FIG. 1B is a cross-sectional view schematically illustrating the semiconductor light-emitting element according to the first embodiment, and FIG. 1C is a bottom view schematically illustrating the semiconductor light-emitting element according to the first embodiment.

Here, FIG. 1B illustrates a cross section at a position taken along line A-A′ in FIG. 1A and FIG. 1C.

A semiconductor light-emitting element 1A according to the first embodiment is a semiconductor light-emitting element having a top and bottom electrode structure which is provided with an LED. The semiconductor light-emitting element 1A includes a substrate 10, a laminated body 30 including a light-emitting layer 30e, a metal containing layer 40, an optical reflection film 41, an electrode 50, electrode pads 51pa and 51pb, wirings 51aa, 51ab, 51b, 51c, and 51d, and a protective layer 70.

The substrate 10 contains silicon (Si). The substrate 10 is, for example, a silicon substrate which is obtained by singulating (dicing) a silicon wafer. The substrate 10 includes a first surface (hereinafter, for example, a bottom surface 10d) and a second surface (hereinafter, for example, a top surface 10u), which is opposite to the bottom surface 10d. The substrate 10 has a predetermined conductivity set by properly adjusting concentration of impurities which are included in the substrate 10.

The electrode 50 is provided on the bottom surface 10d side of the substrate 10. The electrode 50 is a metallic film, and may be a single layer or multiple layers. The electrode is electrically connected to the substrate 10. The electrode 50 can contain at least one or more conductors selected from a group including, for example, aluminum (Al), titanium (Ti), nickel (Ni), tungsten (W), gold (Au), and the like.

The laminated body 30 is provided on the top surface 10u side of the substrate 10. In the laminated body 30, a first semiconductor layer (hereinafter, for example, a p-type semiconductor layer 30p), the light-emitting layer (an active layer) 30e, and a second semiconductor layer (hereinafter, for example, an n-type semiconductor layer 30n) are laminated in this order from the substrate 10 side. Here, the p-type semiconductor layer 30p is a cladding layer of a p-side and the n-type semiconductor layer 30n is a cladding layer of an n-side. In the first embodiment, for example, it is assumed that a p-type is a first conductivity type and an n-type is a second conductivity type.

The p-type semiconductor layer 30p can include a nitride semiconductor. The p-type semiconductor layer 30p contains, for example, magnesium (Mg) which is used as a dopant. The n-type semiconductor layer 30n can also include a nitride semiconductor, such as the same nitride semiconductor used for the p-type semiconductor 30p. The n-type semiconductor layer 30n contains, for example, silicon (Si) which is used as the dopant. The light-emitting layer 30e can also include a nitride semiconductor, such as the same nitride semiconductor used for the p-type semiconductor layer 30p and/or the n-type semiconductor layer 30n. The light-emitting layer 30e may have, for example, a single quantum well (SQW: Single Quantμm Well) structure or a multiple quantum well (MQW: Multi Quantμm Well) structure. A top surface 30nu of the n-type semiconductor layer 30n has roughness so as to improve an extraction effect of light emitted from the light-emitting layer 30e.

The electrode pads 51pa and 51pb are electrically connected to the n-type semiconductor layer 30n of the laminated body 30. When the semiconductor light-emitting element 1A is viewed in a Z direction which extends from the bottom surface 10d of the substrate 10 toward the top surface 10u, the respective electrode pads 51pa and 51pb are positioned in the vicinity of a corner of the semiconductor light-emitting element 1A. The electrode pads 51pa and 51pb can contain at least one metal selected from the group consisting of, for example, aluminum (Al), titanium (Ti), nickel (Ni), tungsten (W), gold (Au), and the like.

The wiring 51aa is electrically connected to the electrode pad 51pa and the n-type semiconductor layer 30n. The width of the wiring 51aa is different between a portion closer to the electrode pad 51pa and a portion farther from the electrode pad 51pa. For example, in the wiring 51aa, the width at a portion farther from the electrode pad 51pa is wider than the width at a portion close to the electrode pad 51pa. Specifically, in the wiring 51aa, a width W2 (for example, 8 μm) at a position P2 is wider than a width W1 (for example, 5 μm) at a position P1. In some embodiments, the width W2 is at least 50 percent wider than the width W1. Thus, the wiring 51aa has a length extending between position P1 and position P2. Here, the position P2 of the wiring 51aa is a position in the vicinity of the corner of the semiconductor light-emitting element 1A. In addition, “width” is defined as the width of the wiring in the direction orthogonal to the extension direction (length direction) of the wiring and orthogonal to the direction in which the layers in the semiconductor light-emitting element 1A are laminated. Furthermore, the position P1 is a position where the wiring 51aa is connected to the electrode pad 51pa and the position P2 is a position which is offset from the position P1 by a predetermined distance, such as near an opposing corner of the semiconductor light-emitting element 1A. For example, the width of the wiring 51aa continuously becomes wider from the position P1 to the position P2. In other words, the width of the wiring 51aa becomes wider as the distance from the electrode pad 51pa increases.

The wiring 51ab is electrically connected to the electrode pad 51pb and the n-type semiconductor layer 30n. The width of the wiring 51ab is different between a portion closer to the electrode pad 51pb and a portion farther from the electrode pad 51pb. For example, in the wiring 51ab as well, the width at a portion far from the electrode pad 51pb is wider than the width at a portion close to the electrode pad 51pb. Specifically, in the wiring 51ab, the width W2 at the position P2 is wider than the width W1 at the position P1. Here, the position P2 of the wiring 51ab is a position in the vicinity of the corner of the semiconductor light-emitting element 1A. The position P1 is a position where the wiring 51ab is connected to the electrode pad 51pb and the position P2 is a position which is offset from the position P1 by a predetermined distance, such as near an opposing corner of the semiconductor light-emitting element 1A. The width of the wiring 51ab continuously becomes wider from the position P1 to the position P2. In other words, the width of the wiring 51ab becomes wider as the distance from the electrode pad 51pb increases.

The wiring 51aa at the position P2 and the wiring 51ab at the position P2 are connected to each other via the wiring 51d. A width W3 of the wiring 51d is wider than the width W2. The wiring 51aa in the vicinity of the position P1 and the wiring 51ab in the vicinity of the position P1 are connected to each other via the wiring 51b. The width of the wiring 51b is, for example, the width W1. In addition, the wiring 51b and the wiring 51d are connected to each other via the wiring 51c. The width at the position where the wiring 51c is connected to the wiring 51b is, for example, the width W1. The width at the position where the wiring 51c is connected to the wiring 51d is, for example, the width W2. The width of the wiring 51c continuously becomes wider from the position where the wiring 51c is connected to the wiring 51b to the position where the wiring 51c is connected to the wiring 51d.

Similar to the wirings 51aa and 51ab, the wirings 51b, 51c, and 51d are electrically connected to the n-type semiconductor layer 30n. The wirings 51aa, 51ab, 51b, 51c, and 51d are integrally formed.

When the wirings 51aa, 51ab, 51b, 51c, and 51d are collectively referred to as a wiring 51, a total area S51 of a cross section of the wiring 51 (e.g., a cross section taken through line Q-Q′ in FIG. 1B) in the directions (i.e., the X direction and the Y direction) parallel with the direction in which each wiring 51 extends, is equal to or less than 40% of a total area S30e in a cross section (e.g., a cross section taken through line P-P′ in FIG. 1B) of the light-emitting layer 30e in the aforementioned parallel direction. That is, the light-emitting layer 30e includes a light-emitting surface contacting the p-type semiconductor layer, and total area of the wiring 51 parallel to the light-emitting surface is 40% or less of the total area of the light-emitting surface. The wiring 51 contains at least one conductor such as silver (Ag), aluminum (Al), gold (Au), and the like.

The metal containing layer 40 is provided between the laminated body 30 and the substrate 10. The metal containing layer 40 is a bonding material which bonds the laminated body 30 and the substrate 10. The metal containing layer 40 contains metal or a metal compound.

The optical reflection film 41 is provided between the laminated body 30 and the metal containing layer 40. The optical reflection film 41 contains at least one element selected from a group including gold (Au), silver (Ag), aluminum (Al), zinc (Zn), zirconium (Zr), silicon (Si), germanium (Ge), platinum (Pt), rhodium (Rh), nickel (Ni), palladium (Pd), copper (Cu), tin (Sn), carbon (C), magnesium (Mg), chromium (Cr), tellurium (Te), selenium (Se), titanium (Ti), oxygen (O), hydrogen (H), tungsten (W), molybdenum (Mo).

The optical reflection film 41 may be a multi layer film stack. In this case, the each layer of the multi layer contains at least one element selected from the group including gold (Au), silver (Ag), aluminum (Al), zinc (Zn), zirconium (Zr), silicon (Si), germanium (Ge), platinum (Pt), rhodium (Rh), nickel (Ni), palladium (Pd), copper (Cu), tin (Sn), carbon (C), magnesium (Mg), chromium (Cr), tellurium (Te), selenium (Se), titanium (Ti), oxygen (O), hydrogen (H), tungsten (W), molybdenum (Mo).

In order to improve heat resistance and chemical resistance of the optical reflection film 41, the material of the optical reflection film 41 may be an alloy containing two or more elements from the above described metal group.

In addition, the protective layer 70 is provided above the side portion of the laminated body 30 and to a portion inside the laminated body 30 from the side portion of the laminated body 30.

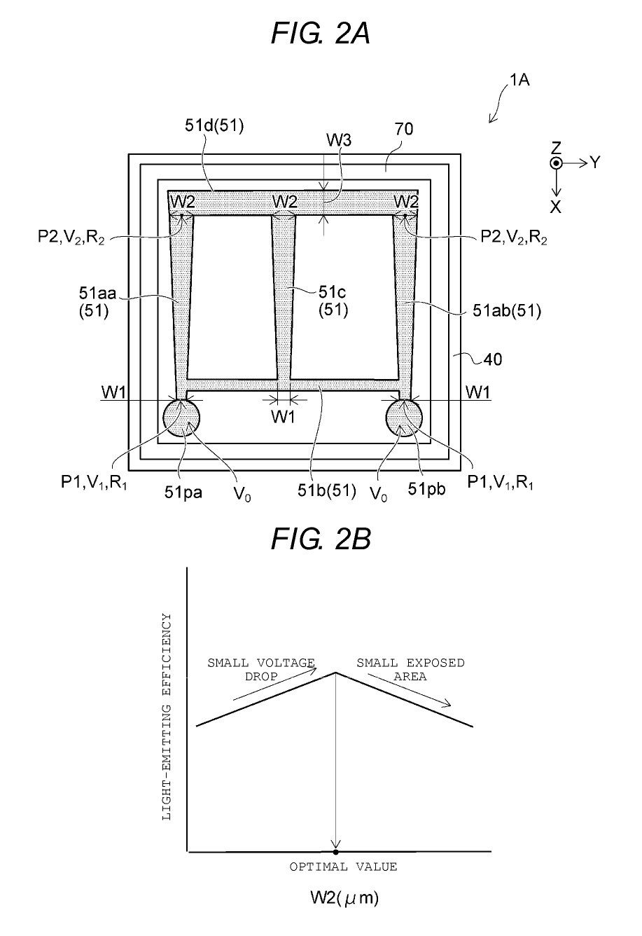

FIG. 2A is a top view schematically illustrating an effect of the semiconductor light-emitting element according to the first embodiment, and FIG. 2B is a diagram illustrating an example of relationship between the width of the wiring of the semiconductor light-emitting element and the light-emitting efficiency according to the first embodiment.

Here, the light-emitting efficiency is defined as a value obtained by dividing a total luminous flux emitted from the semiconductor light-emitting element by electric power which is injected to the semiconductor light-emitting element.

In the semiconductor light-emitting element 1A as illustrated in FIG. 2A, if a potential V₀ is applied to the electrode pads 51pa and 51pb, the potential V₀ is transmitted to the wiring 51 (the wirings 51aa, 51ab, 51b, 51c, and 51d). The potential V₀ is a potential having a value lower than that of a potential V₁ applied to the electrode 50 which is a bottom electrode. In this way, the forward bias voltage is applied between the p-type semiconductor layer 30p and the n-type semiconductor layer 30n.

Here, in the wiring 51aa, the width W2 at the position P2 is wider than the width W1 at the position P1. In other words, in the wiring 51aa, a resistance R₂ at the position P2 is smaller than a resistance R₁ at the position P1 (R₂<R₁). Accordingly, in the wiring 51aa, a voltage drop is not easily generated between the position P1 and the position P2.

In addition, in the wiring 51ab, the width W2 at the position P2 is wider than the width W1 at the position P1. In other words, in the wiring 51ab, the resistance R₂ at the position P2 is smaller than the resistance R₁ at the position P1 (R₂<R₁). Accordingly, in the wiring 51ab, a voltage drop is not easily generated between the position P1 and the position P2.

Further, the width W3 of the wiring 51d which is connected to the wiring 51aa and the wiring 51ab is wider than the width W2. In addition, the potential is supplied to the wiring 51d from both of the wiring 51aa and the wiring 51ab. For this reason, when the potential is applied to the wiring 51d from the wirings 51aa and 51ab, a voltage drop is not easily generated.

In addition, to the wiring 51b which is connected to the wiring 51aa and the wiring 51ab, the potential is supplied from both of the wiring 51aa and the wiring 51ab. Then, the wiring 51c is connected between the wiring 51b and the wiring 51d. The width of the wiring 51c becomes wider from W1 to W2 as wiring 51c extends closer to the wiring 51d from the wiring 51b. Accordingly, a voltage drop is also not easily generated in the inside of the wiring 51c as well.

Therefore, in the semiconductor light-emitting element 1A, if the potential V₀ is applied to the electrode pads 51pa and 51pb, substantially the same potential is applied to the entirety of the wiring 51. Owing to this, the potential is substantially uniformly applied to the n-type semiconductor layer 30n as well, the light intensity emitted from the light-emitting layer 30e is enhanced, and the light-emitting efficiency is improved.

Note that each of the widths W1 to W3 of the wiring 51 has an optimal value. For example, the width W2 at the position P2 of the wiring 51aa is used as an example to describe that each of the widths of the wiring 51 has the optimal value.

For example, as illustrated in FIG. 2B, if the width W2 becomes gradually wider starting from narrower widths, the voltage drop generated in the wiring 51aa is further alleviated, thereby improving the light-emitting efficiency. However, if the width W2 of the wiring 51aa keeps increasing and becomes too large, an exposed area of the n-type semiconductor layer 30n is reduced by the wiring 51aa, thereby ending up shielding the light emitted from the light-emitting layer 30e.

Thus, when the width W2 becomes a certain width or greater, the light-emitting efficiency becomes deteriorated since a shielding effect by the wiring becomes more influential on the light-emitting efficiency than the alleviation of the voltage drop. Then, if the width W2 further widens, the light-emitting efficiency is further deteriorated.

In the semiconductor light-emitting element 1A, the width W2 can be adjusted to increase the light-emitting efficiency, and each of the widths W1 and W3 can also be adjusted maximize the light-emitting efficiency.

By adjusting each of the widths W1 to W3, the voltage drop can be alleviated in the wiring 51 and the shielding effect of the light by the wiring 51 can be suppressed. For example, the aforementioned total area S51 is set to 40% or less of the total area S30e. Therefore, it is possible to obtain the high light-emitting efficiency in the semiconductor light-emitting element 1A.

(Modification Example of First Embodiment)

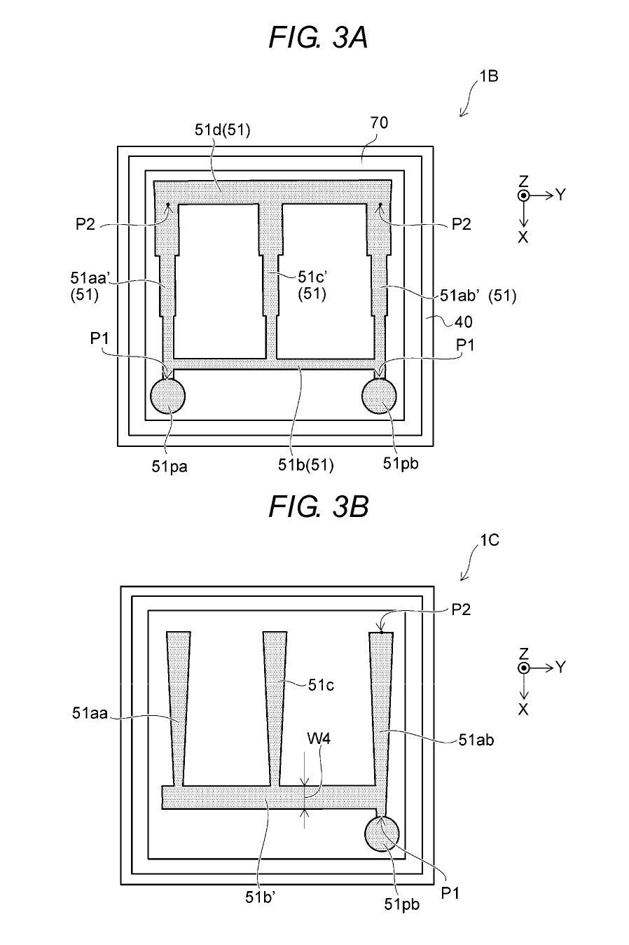

FIG. 3A is a top view schematically illustrating a semiconductor light-emitting element according to a first modification example of the first embodiment, and FIG. 3B is a top view schematically illustrating a semiconductor light-emitting element according to a second modification example of the first embodiment.

In a semiconductor light-emitting element 1B as illustrated in FIG. 3A, the width of a wiring 51aa′ becomes wider step-wise from the position P1 to the position P2 of the wiring 51aa′. In other words, the width of the wiring 51aa′ becomes wider step-wise as the wiring 51aa′ extends further from the electrode pad 51pa. In addition, the width of a wiring 51ab′ becomes wider step-wise from the position P1 to the position P2 of the wiring 51ab′. It means that the width of the wiring 51ab′ becomes wider as the wiring 51ab′ extends further from the electrode pad 51pb. Further, the width of a wiring 51c′ becomes wider step-wise from a wiring 51b toward the wiring 51d.

In this structure, the voltage drop generated in each of the wiring 51aa′, the wiring 51ab′, and the wiring 51c′ is alleviated, thereby improving the light-emitting efficiency.

One electrode pad 51pb is disposed as the electrode pad in a semiconductor light-emitting element 1C as illustrated in FIG. 3B.

The wiring 51ab is connected to the electrode pad 51pb. A wiring 51b′ is connected to the wiring 51ab in the vicinity of the position P1. The wiring 51b′ is substantially orthogonal to the wiring 51ab. The width of the wiring 51b′ is, for example, the same as the width W2 or wider than the width W2. In addition, the wiring 51aa and the wiring 51c are connected to the wiring 51b′.

In this structure, from the position P1 to the position P2 of the wiring 51ab, the width of the wiring 51ab continuously becomes wider. In addition, the width of the wiring 51aa and the width of the wiring 51c continuously grow wider as the wirings 51aa, 51c extend further from the wiring 51b′. Accordingly, the voltage drop, which is generated in the inside of each of the wiring 51ab, the wiring 51aa, and the wiring 51c, is alleviated. Thus the light-emitting efficiency is improved.

### Second Embodiment

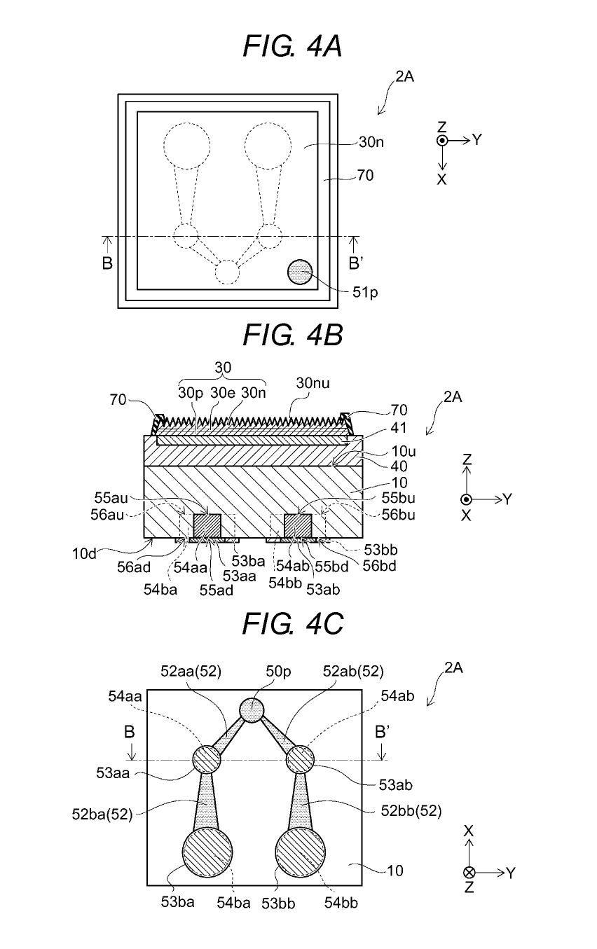

FIG. 4A is a top view schematically illustrating a semiconductor light-emitting element according to a second embodiment, FIG. 4B is a cross-sectional view schematically illustrating the semiconductor light-emitting element according to the second embodiment, and FIG. 4C is a bottom view schematically illustrating the semiconductor light-emitting element according to the second embodiment.

Here, FIG. 4B illustrates a cross-sectional view taken along line B-B′ in FIG. 4A and FIG. 4C.

A semiconductor light-emitting element 2A includes the substrate 10, the laminated body 30, the metal containing layer 40, the optical reflection film 41, a first electrode pad (hereinafter, for example, an electrode pad 50p), a first wiring (hereinafter, for example, wirings 52aa and 52ab), a second wiring (hereinafter, for example, wirings 52ba and 52bb), wirings 53aa, 53ab, 53ba, and 53bb, a first electrode layer (hereinafter, for example, electrode layers 54aa and 54ab), a second electrode layer (hereinafter, for example, electrode layers 54ba and 54bb), a second electrode pad (hereinafter, for example, an electrode pad 51p), and the protective layer 70. Here, the wirings 52aa, 52ab, 52ba, and 52bb are collectively referred to as a wiring 52.

The electrode pad 50p is provided on the bottom surface 10d side of the substrate 10. The electrode pad 50p is electrically connected to the substrate 10. The electrode pad 50p is positioned between corners of the semiconductor light-emitting element 2A, such as between the corners of the bottom surface 10d of the substrate 10. The electrode pad 51p is electrically connected to the n-type semiconductor layer 30n. The electrode pad 51p is positioned in the vicinity of another corner of the semiconductor light-emitting element 2A.

The electrode layer 54aa is electrically connected to the electrode pad 50p via the wiring 52aa and the wiring 53aa. An upper end 55au of the electrode layer 54aa is positioned in the substrate 10. A lower end 55ad of the electrode layer 54aa is connected to the wiring 53aa. The width of the wiring 52aa continuously becomes wider from the electrode pad 50p to the electrode layer 54aa, such as for example, an increase of width by at least 10 percent.

The electrode layer 54ab is electrically connected to the electrode pad 50p via the wiring 52ab and the wiring 53ab. An upper end 55bu of the electrode layer 54ab is positioned in the substrate 10. A lower end 55bd of the electrode layer 54ab is connected to the wiring 53ab. The width of the wiring 52ab continuously becomes wider from the electrode pad 50p to the electrode layer 54ab, such as for example, an increase of width by at least 10 percent. The width of the second wiring 52ba located at the second electrode layer 54ba is wider than the width of the first wiring 52aa located at the first electrode layer 54aa, such as for example, an increase of width by at least 10 percent.

The electrode layer 54ba is electrically connected to the electrode pad 50p via the wiring 53ba, the wiring 52ba, the wiring 53aa, and the wiring 52aa. An upper end 56au of the electrode layer 54ba is positioned in the substrate 10. A lower end 56ad of the electrode layer 54ba is connected to the wiring 53ba. The distance between the electrode layer 54ba and the electrode pad 50p is greater than the distance between the electrode layer 54aa and the electrode pad 50p.

An area of a cross section of the electrode layer 54ba which is cut along the direction orthogonal to the Z direction is larger than an area of a cross section of the electrode layer 54aa which is cut along the direction orthogonal to the Z direction. For example, when the cross section is in a circular shape, the diameter of the electrode layer 54aa is 20 μm and the diameter of the electrode layer 54ba is 25 μm. The wiring 52ba is electrically connected to the electrode layer 54aa and the electrode layer 54ba. The width of the wiring 52ba continuously becomes wider from the electrode layer 54aa to the electrode layer 54ba.

The electrode layer 54bb is electrically connected to the electrode pad 50p via the wiring 53bb, the wiring 52bb, the wiring 53ab, and the wiring 52ab. An upper end 56bu of the electrode layer 54bb is positioned in the substrate 10. The distance between the electrode layer 54bb and the electrode pad 50p is greater than the distance between the electrode layer 54ab and the electrode pad 50p. A lower end 56bd of the electrode layer 54bb is connected to the wiring 53bb.

An area of a cross section of the electrode layer 54bb which is cut along the direction orthogonal to the Z direction is larger than an area of a cross section of the electrode layer 54ab which is cut along the direction orthogonal to the Z direction. For example, when the cross section is in a circular shape, the diameter of the electrode layer 54ab is 20 μm and the diameter of the electrode layer 54bb is 25 μm. The wiring 52bb is electrically connected to the electrode layer 54ab and the electrode layer 54bb. The width of the wiring 52bb continuously becomes wider from the electrode layer 54ab to the electrode layer 54bb.

In the semiconductor light-emitting element 2A, if the potential V₁ is applied to the electrode pad 50p, the potential V₁ is applied to each of the wirings 52aa, 53aa, 52ba, and 53ba and applied to each of the wirings 52ab, 53ab, 52bb, and 53bb. Here, the potential V₁ is the potential having a value higher than that of the potential V₀ applied to the electrode pad 51p which is the upper electrode. Therefore, the forward bias voltage is applied between the p-type semiconductor layer 30p and the n-type semiconductor layer 30n.

In the wiring 52aa, the width in the vicinity of the electrode layer 54aa is wider than the width in the vicinity of the electrode pad 50p. In other words, in the wiring 52aa, the resistance in the vicinity of the electrode layer 54aa is smaller than the resistance in the vicinity of the electrode pad 50p. Accordingly, in the wiring 52aa, a voltage drop is not easily generated between the electrode pad 50p and the electrode layer 54aa.

In addition, in the wiring 52ab, the width in the vicinity of the electrode layer 54ab is wider than the width in the vicinity of the electrode pad 50p. In other words, in the wiring 52ab, the resistance in the vicinity of the electrode layer 54ab is smaller than the resistance in the vicinity of the electrode pad 50p. Accordingly, in the wiring 52ab, a voltage drop is not easily generated between the electrode pad 50p and the electrode layer 54ab.

Further, in the wiring 52ba, the width in the vicinity of the electrode layer 54ba is wider than the width in the vicinity of the electrode layer 54aa. In other words, in the wiring 52ba, the resistance in the vicinity of the electrode layer 54ba is smaller than the resistance in the vicinity of the electrode layer 54aa. Accordingly, in the wiring 52ba, a voltage drop is not easily generated between the electrode layer 54aa and the electrode layer 54ba.

Further, in the wiring 52bb, the width in the vicinity of the electrode layer 54bb is wider than the width in the vicinity of the electrode layer 54ab. In other words, in the wiring 52bb, the resistance in the vicinity of the electrode layer 54bb is smaller than the resistance in the vicinity of the electrode layer 54ab. Accordingly, in the wiring 52bb, a voltage drop is not easily generated between the electrode layer 54ab and the electrode layer 54bb.

With regard to the electrode layers 54aa and 54ba which are embedded in the substrate 10, the diameter of the electrode layer 54ba is wider than the diameter of the electrode layer 54aa. Similarly, with regard to the electrode layer 54ab and 54bb which are also embedded in the substrate 10, the diameter of the electrode layer 54bb is wider than the diameter of the electrode layer 54ab.

Therefore, in the semiconductor light-emitting element 2A, if the potential V₁ is applied to the electrode pad 50P, substantially the same potential is applied to the entire wiring 52 and substantially the same potential is applied to the electrode layers 54aa, 54ab, 54ba, and 54bb. In this way, the potential V₁ is substantially uniformly applied to the substrate 10 and the intensity of the light emitted from the light-emitting layer 30e substantially becomes uniform.

In addition, if the substrate 10 contains silicon, the resistivity of the substrate 10 ends up higher than that of the general metal. In the second embodiment, the electrode layers 54aa, 54ab, 54ba, and 54bb which are in a pin shape are embedded in the substrate 10 and thus an electrical current which is injected from the substrate 10 side is efficiently distributed in the substrate 10. In this way, it is possible to obtain the high light-emitting efficiency in the semiconductor light-emitting element 2A.

(First Modification Example of Second Embodiment)

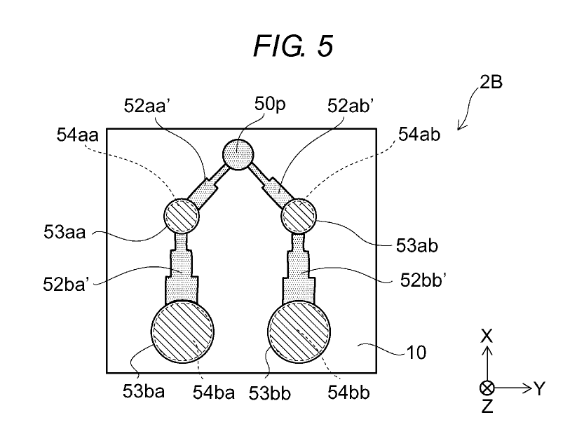

FIG. 5 is a bottom view schematically illustrating a semiconductor light-emitting element according to a first modification example of a second embodiment.

In a semiconductor light-emitting element 2B as illustrated in FIG. 5, the width of a wiring 52aa′ becomes wider step-wise from the electrode pad 50p to the electrode layer 54aa. In addition, the width of a wiring 52ab′ becomes wider step-wise from the electrode pad 50p to the electrode layer 54ab. The width of a wiring 52ba′ becomes wider step-wise from the electrode layer 54aa to the electrode layer 54ba. The width of a wiring 52bb′ becomes wider step-wise from the electrode layer 54ab to the electrode layer 54bb.

Even with this structure, the voltage drop generated in each of the wirings 52aa′, 52ab′, 52ba′, and 52bb′ is further alleviated, thereby improving the light-emitting efficiency.

### Third Embodiment

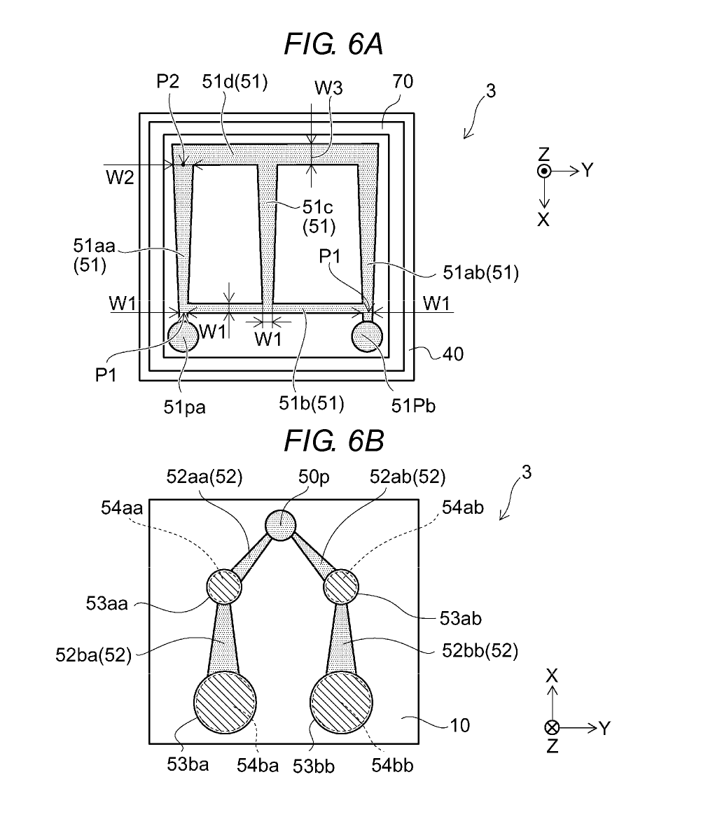

FIG. 6A is a top view schematically illustrating a semiconductor light-emitting element according to a third embodiment, and FIG. 6B is a bottom view schematically illustrating the semiconductor light-emitting element according to the third embodiment.

A semiconductor light-emitting element 3 as illustrated in FIG. 6A and FIG. 6B has a structure obtained by combining the electrode structure on the upper side of the semiconductor light-emitting element 1A according to the first embodiment with the electrode structure on the lower side of the semiconductor light-emitting element 2A according to the second embodiment. In this structure, it is possible to obtain the high light-emitting efficiency.

### Fourth Embodiment

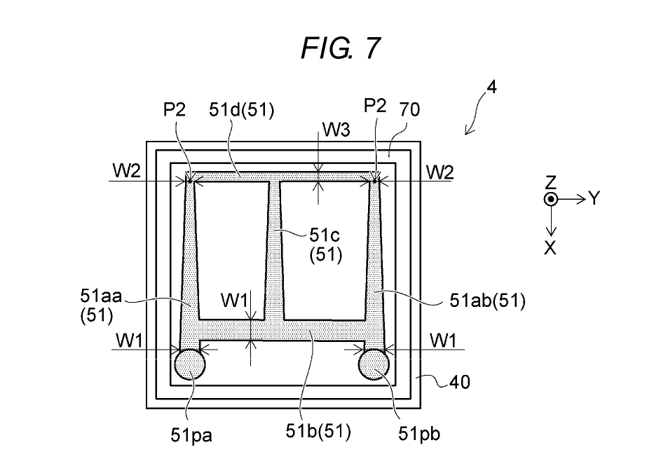

FIG. 7 is a top view schematically illustrating a semiconductor light-emitting element according to a fourth embodiment.

In a semiconductor light-emitting element 4 according to the fourth embodiment, in the wiring 51aa, the width at a portion further from the electrode pad 51pa is narrower than the width at a portion closer to the electrode pad 51pa. Specifically, in the wiring 51aa, the width W2 at the position P2 is narrower than the width W1 at the position P1. For example, the width of the wiring 51aa continuously becomes narrower from the position P1 to the position P2. In other words, the width of the wiring 51aa becomes smaller as a distance from the electrode pad 51pa increases.

Similarly, in the wiring 51ab, the width at a portion further from the electrode pad 51pb is narrower than the width at a portion closer to the electrode pad 51pb. Specifically, in the wiring 51ab, the width W2 at the position P2 is narrower than the width W1 at the position P1. For example, the width of the wiring 51ab continuously becomes narrower from the position P1 to the position P2. In other words, the width of the wiring 51ab becomes narrower as a distance from the electrode pad 51pb increases.

The wiring 51aa at the position P2 and the wiring 51ab at the position P2 are connected to each other via the wiring 51d. The width W3 of the wiring 51d is narrower than the width W2. The wiring 51aa in the vicinity of the position P1 and the wiring 51ab in the vicinity of the position P1 are connected to each other via the wiring 51b. The width of the wiring 51b is, for example, the width W1. In addition, the wiring 51b and the wiring 51d are connected to each other via the wiring 51c. The width at the position where the wiring 51c is connected to the wiring 51b is, for example, the width W1. The width at the position where the wiring 51c is connected to the wiring 51d is, for example, the width W2. The width of the wiring 51c continuously becomes narrower from the position where the wiring 51c is connected to the wiring 51b to the position where the wiring 51c is connected to the wiring 51d.

For example, when the resistance of the wiring 51 is relatively low, if it is assumed that the width of the wiring 51 is the same in any positions, the electrical current which is injected from the electrode pads 51pa and 51pb to the n-type semiconductor layer 30n is likely to preferentially flow into the n-type semiconductor layer 30n below the electrode pads 51pa and 51pb rather than the wiring 51.

In the fourth embodiment, for example, the width of the wirings 51aa and 51ab becomes narrower as a distance from the electrode pads 51pa and 51pb increases. Therefore, the resistance of the wiring 51 in the vicinity of the electrode pads 51pa and 51pb is lower than the resistance of the wiring 51 which is further from the electrode pads 51pa and 51pb. Accordingly, substantially the same potential is applied to the entirety of the wiring 51. With this, the potential is substantially uniformly applied to the n-type semiconductor layer 30n as well, the intensity of the light emitted from the light-emitting layer 30e is enhanced and the light-emitting efficiency is improved.

As described above, specific examples are given of the embodiments. However, the embodiments are not limited thereto. That is, as long as additional embodiments or modifications are obtained using the design of the aforementioned specific examples, it is possible for such further embodiments and modifications be included within the scope of the embodiments described above. Respective elements and dispositions, materials, conditions, shapes, and sizes which are included in the aforementioned specific examples are not limited to the examples but can be changed as necessary.

In addition, combinations of two or more of the elements in the embodiments described above to the extent technically possible are also included in the range of the embodiments provided. Besides, various modification examples and correction examples may also be perceived by those skilled in the related art, and these modification examples and correction examples are also understood to fall within the range of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting element, comprising:
a first semiconductor layer of a first conductivity type;
a second semiconductor layer of a second conductivity type;
a light-emitting layer between the first semiconductor layer and the second semiconductor layer;
one or more electrode pads including a first electrode pad; and
one or more wirings electrically connected between the one or more electrode pads and the second semiconductor layer, the one or more wirings including a first wiring connected to the first electrode pad, the first wiring having a length and a width each substantially parallel to the light-emitting surface, wherein the length is greater than the width, and the width changes between a first portion and a second portion, wherein the first portion is closer to the first electrode pad than the second portion is to the first electrode pad.

2. The semiconductor light-emitting element according to claim 1, wherein
a total cross-sectional area of all wirings between all electrode pads and the second semiconductor layer is 40% or less than a total cross-sectional area of the light emitting layer, and
the total cross-sectional area in a plane parallel to the light-emitting layer.

3. The semiconductor light-emitting element according to claim 2, wherein the width of the first wiring at the second portion is wider than the width of the first wiring at the first portion.

4. The semiconductor light-emitting element according to claim 1, wherein the width of the first wiring continuously increases from the first portion to the second portion.

5. The semiconductor light-emitting element according to claim 1, wherein the width of the first wiring at the second portion is at least 50 percent wider than the width at the first portion.

6. The semiconductor light-emitting element according to claim 1, wherein
the one or more wirings further comprises a second wiring electrically connected to the first wiring, the second wiring having a width and a length each substantially parallel to the light-emitting layer, and
the widths of the first wiring and the second wiring each change in a same pattern along the respective lengths of each wiring.

7. The semiconductor light-emitting element according to claim 1, wherein the width of the first wiring increases in a step-wise pattern from the first portion to the second portion.

8. The semiconductor light-emitting element according to claim 7, wherein the width of the first wiring at the second portion is at least 10 percent wider than the width at the first portion.

9. The semiconductor light-emitting element according to claim 7, wherein the one or more wirings further comprises a second wiring electrically connected to the first wiring, the second wiring having a width and a length each substantially parallel to the light-emitting layer, and the widths of the first wiring and the second wiring each change in a same pattern along respective lengths of each wiring.

10. The semiconductor light-emitting element according to claim 1, wherein the width of the first wiring at the first portion is wider than the width of the first wiring at the second portion.

11. The semiconductor light-emitting element according to claim 1, wherein the width of the first wiring continuously decreases from the first portion to the second portion.

12. A semiconductor light-emitting element, comprising:
a substrate having a first surface on first side and a second surface on a second side opposite to the first side;
a first electrode pad on the first side of the substrate and electrically connected to the substrate;
a plurality of electrode layers including:
a first electrode layer electrically connected to the first electrode pad, an upper end of the first electrode layer being positioned in the substrate, and
a second electrode layer electrically connected to the first electrode pad, an upper end of the second electrode layer being positioned in the substrate, wherein
a first distance between the first electrode pad and the first electrode layer is less than a second distance between the first electrode pad and the second electrode layer, and
a cross-sectional area of the first electrode layer parallel to the first surface is less than a cross-sectional area of the second electrode layer parallel to the first surface;
a laminated body on the second side of the substrate, the laminated body including a first semiconductor layer of a first conductivity type, a second semiconductor layer of a second conductivity type, and a light-emitting layer between the first semiconductor layer and the second semiconductor layer; and
a second electrode pad electrically connected to the second semiconductor layer.

13. The semiconductor light-emitting element according to claim 12, further comprising:
a first wiring electrically connected between the first electrode pad and the first electrode layer, the first wiring having a width substantially parallel to the first surface, wherein the width of the first wiring continuously becomes wider from the first electrode pad to the first electrode layer.

14. The semiconductor light-emitting element according to claim 13, further comprising:
a second wiring electrically connected between the first electrode layer and the second electrode layer, the second wiring having a width substantially parallel to the first surface, wherein the width of the second wiring continuously becomes wider from the first electrode layer to the second electrode layer.

15. The semiconductor light-emitting element according to claim 14, wherein the width of the second wiring located at the second electrode layer is wider than the width of the first wiring located at the first electrode layer.

16. The semiconductor light-emitting element according to claim 12, further comprising:
a first wiring electrically connected between the first electrode pad and the first electrode layer, the first wiring having a width substantially parallel to the first surface, wherein the width of the first wiring becomes wider in a step-wise pattern from the first electrode pad to the first electrode layer.

17. The semiconductor light-emitting element according to claim 16, further comprising:
a second wiring electrically connected between the first electrode layer and the second electrode layer, the second wiring having a width substantially parallel to the first surface, wherein the width of the second wiring becomes wider in a step-wise pattern from the first electrode layer to the second electrode layer.

18. The semiconductor light-emitting element according to claim 17, wherein the width of the second wiring located at the second electrode layer is wider than the width of the first wiring located at the first electrode layer.

19. A semiconductor light-emitting element, comprising:
a substrate having a first surface on first side and a second surface on a second side opposite to the first side;
a first electrode pad provided on the first side of the substrate and electrically connected to the substrate;
a plurality of electrode layers including:
a first electrode layer electrically connected to the first electrode pad, an upper end of the first electrode layer being positioned in the substrate, and
a second electrode layer electrically connected to the first electrode pad, an upper end of the second electrode layer being positioned in the substrate, wherein a first distance between the first electrode pad and the first electrode layer is less than a second distance between the first electrode pad and the second electrode layer; and
a first wiring electrically connected between the first electrode pad and the first electrode layer, the first wiring having a width substantially parallel to the first surface, wherein the width of the first wiring continuously becomes wider from the first electrode pad to the first electrode layer;
a laminated body on the second side of the substrate, the laminated body including a first semiconductor layer of a first conductivity type, a second semiconductor layer of a second conductivity type, and a light-emitting layer between the first semiconductor layer and the second semiconductor layer; and
a second electrode pad electrically connected to the second semiconductor layer.

20. The semiconductor light-emitting element according to claim 19, further comprising:
a second wiring electrically connected between the first electrode layer and the second electrode layer, the second wiring having a width substantially parallel to the first surface, wherein the width of the second wiring continuously becomes wider from the first electrode layer to the second electrode layer.
